(19) United States
(12) Patent Application Publication
(10) Pub. No.: US 2022/0209095 A1
(43) Pub. Date: Jun. 30, 2022

(54) PIEZOELECTRIC ELEMENT AND METHOD FOR MANUFACTURING THE SAME

(71) Applicant: Murata Manufacturing Co., Ltd., Nagaokakyo-shi (JP)

(72) Inventors: Shinsuke IKEUCHI, Nagaokakyo-shi (JP); Masato KOBAYASHI, Nagaokakyo-shi (JP); Masayuki SUZUKI, Nagaokakyo-shi (JP); Fumiya KUROKAWA, Nagaokakyo-shi (JP); Yutaka KISHIMOTO, Nagaokakyo-shi (JP); Hajime YAMADA, Nagaokakyo-shi (JP)

(21) Appl. No.: 17/694,729

(22) Filed: Mar. 15, 2022

Related U.S. Application Data
(63) Continuation of application No. PCT/JP2020/020539, filed on May 25, 2020.

(30) Foreign Application Priority Data
Sep. 17, 2019 (JP) 2019-168493

(51) Int. Cl. H01L 41/047; H01L 41/053; H01L 41/29; H01L 41/312; H01L 41/187

(52) U.S. Cl. CPC H01L 41/047; H01L 41/053; H01L 41/332; H01L 41/312; H01L 41/1873; H01L 41/29

(57) ABSTRACT

A piezoelectric element includes a piezoelectric layer, a first electrode layer, and a second electrode layer. The piezoelectric layer includes first and second surfaces opposed to each other. The first electrode layer is located on the first surface. The second electrode layer is located on the second surface. At least a portion of the second electrode layer faces the first electrode layer with the piezoelectric layer interposed therebetween. The second electrode layer mainly includes silicon. The piezoelectric layer is monocrystalline.

### CROSS REFERENCE TO RELATED APPLICATIONS

This application claims the benefit of priority to Japanese Patent Application No. 2019-168493 filed on Sep. 17, 2019 and is a Continuation Application of PCT Application No. PCT/JP2020/020539 filed on May 25, 2020. The entire contents of each application are hereby incorporated herein by reference.

### BACKGROUND OF THE INVENTION

### 1. Field of the Invention

The present invention relates to a piezoelectric element and a method for manufacturing the same.

### 2. Description of the Related Art

Japanese Unexamined Patent Application Publication No. 2009-302661 discloses a configuration of a piezoelectric element. A piezoelectric element disclosed in Japanese Unexamined Patent Application Publication No. 2009-302661 includes a silicon substrate, a piezoelectric film, and a conductive film. The piezoelectric film is made of a piezoelectric, for example, aluminum nitride (AlN) and is disposed on the silicon substrate. The conductive film is made of a conductive material and is disposed on the piezoelectric film. An AIN film is formed such that a film is formed by a reactive magnetron sputtering method and is patterned by reactive ion etching (RIE) using a chlorine-based gas.

In a piezoelectric element in the related art, a piezoelectric layer formed on an electrode layer made of silicon is polycrystalline. Grain boundaries are present in the piezoelectric layer, which is polycrystalline. The permittivity of the piezoelectric layer, which is polycrystalline, tends to be relatively high due to the presence of the grain boundaries and, in association with this, the electrostatic capacitance of the piezoelectric layer also tends to be high. When the electrostatic capacitance of the piezoelectric layer is high, the value of the electrical impedance of the piezoelectric layer is low. Therefore, when a voltage is applied between the electrode layer, which is made of silicon, and a conductive film located on the piezoelectric layer, the voltage distributed to the electrode layer, which is made of silicon is high and the voltage distributed to the piezoelectric layer is low. Therefore, the piezoelectric element in the related art has low driving efficiency.

### SUMMARY OF THE INVENTION

Preferred embodiments of the present invention provide piezoelectric elements each having an improved driving efficiency.

A piezoelectric element according to a preferred embodiment of the present invention includes a piezoelectric layer, a first electrode layer, and a second electrode layer. The piezoelectric layer includes a first surface and a second surface. The second surface is opposed to the first surface. The first electrode layer is on the first surface. The second electrode layer is on the second surface. At least a portion of the second electrode layer faces the first electrode layer with the piezoelectric layer interposed therebetween. The second electrode layer mainly includes silicon. The piezoelectric layer is monocrystalline.

A method for manufacturing a piezoelectric element according to a preferred embodiment of the present invention includes bonding a second electrode layer and depositing a first electrode layer. In the bonding the second electrode layer, the second electrode layer is bonded, by surface activated bonding or atomic diffusion bonding, to a side of a second surface of a piezoelectric layer including a first surface and the second surface opposed to the first surface. In the depositing the first electrode layer, the first electrode layer is deposited on a side of the first surface of the piezoelectric layer such that at least a portion of the first electrode layer faces the second electrode layer with the piezoelectric layer interposed therebetween. The second electrode layer mainly includes silicon. The piezoelectric layer is monocrystalline.

According to preferred embodiments of the present invention, the driving efficiency of a piezoelectric element is improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of a piezoelectric element according to a first preferred embodiment of the present invention.

FIG. 2 is a sectional view of the piezoelectric element viewed in the direction of an arrow of the line II-II of FIG. 1.

FIG. 3 is a sectional view of the piezoelectric element viewed in the direction of an arrow of the line III-III of FIG. 1.

FIG. 4 is a diagram illustrating an equivalent circuit of the piezoelectric element according to the first preferred embodiment of the present invention.

FIG. 5 is a schematic view of a portion of a membrane section of the piezoelectric element according to the first preferred embodiment of the present invention.

FIG. 6 is a schematic view of a portion of the membrane section, in operation, of the piezoelectric element according to the first preferred embodiment of the present invention.

FIG. 7 is an illustration in which a piezoelectric monocrystalline substrate is prepared in a method for manufacturing the piezoelectric element according to the first preferred embodiment of the present invention.

FIG. 8 is an illustration in which a multilayer substrate including a second electrode layer is prepared in the method for manufacturing the piezoelectric element according to the first preferred embodiment of the present invention.

FIG. 9 is an illustration illustrating a state in which the piezoelectric monocrystalline substrate is bonded to the multilayer substrate including the second electrode layer in the method for manufacturing the piezoelectric element according to the first preferred embodiment of the present invention.

FIG. 10 is a sectional view illustrating a state in which a piezoelectric layer is formed by grinding the piezoelectric monocrystalline substrate in the method for manufacturing the piezoelectric element according to the first preferred embodiment of the present invention.

FIG. 11 is a sectional view illustrating a state in which a first electrode layer is disposed in the method for manufacturing the piezoelectric element according to the first preferred embodiment of the present invention.

FIG. 12 is a sectional view illustrating a state in which pores and the like are formed in the piezoelectric layer in the method for manufacturing the piezoelectric element according to the first preferred embodiment of the present invention.

FIG. 13 is a sectional view illustrating a state in which pores and the like are formed in the second electrode layer in the method for manufacturing the piezoelectric element according to the first preferred embodiment of the present invention.

FIG. 14 is an illustration illustrating a state in which an opening is provided on the opposite side of the multilayer substrate, which includes the second electrode layer, from the second electrode layer side in the method for manufacturing the piezoelectric element according to the first preferred embodiment of the present invention.

FIG. 15 is a plan view of a piezoelectric element according to a second preferred embodiment of the present invention.

FIG. 16 is a sectional view of the piezoelectric element viewed in the direction of an arrow of the line XVI-XVI of FIG. 15.

FIG. 17 is a plan view of a piezoelectric element according to a third preferred embodiment of the present invention.

FIG. 18 is a sectional view of the piezoelectric element viewed in the direction of an arrow of the line XVIII-XVIII of FIG. 17.

### DETAILED DESCRIPTION OF THE PREFERRED EMBODIMENTS

Piezoelectric elements according to preferred embodiments of the present invention are described below with reference to drawings. In the description of the preferred embodiments below, the same or corresponding components in the drawings are denoted by the same reference numerals and will not be repeatedly described.

### First Preferred Embodiment

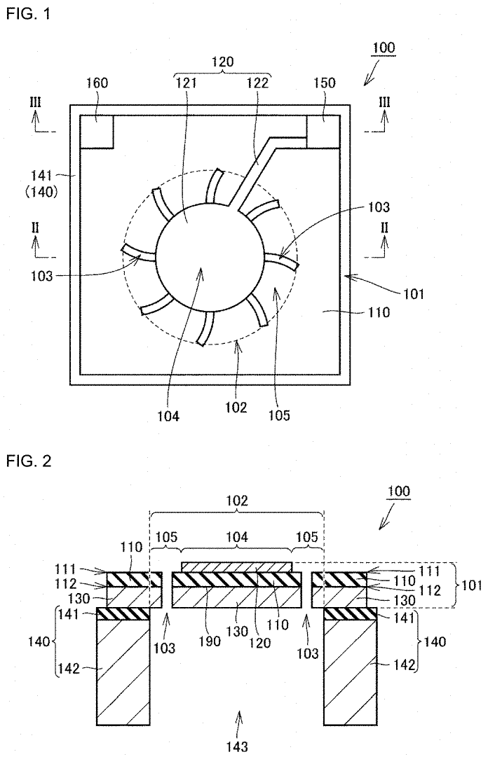

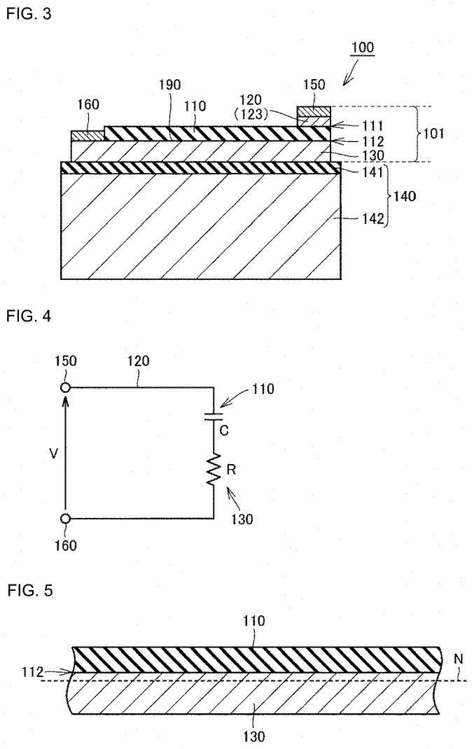

FIG. 1 is a plan view of a piezoelectric element according to a first preferred embodiment of the present invention. FIG. 2 is a sectional view of the piezoelectric element viewed in the direction of an arrow of the line II-II of FIG. 1. FIG. 3 is a sectional view of the piezoelectric element viewed in the direction of an arrow of the line of FIG. 1.

As illustrated in FIGS. 1 to 3, a piezoelectric element 100 according to a first preferred embodiment of the present invention includes a piezoelectric layer 110, a first electrode layer 120, a second electrode layer 130, a base section 140, a first connection electrode 150, and a second connection electrode 160.

As illustrated in FIG. 2, the piezoelectric layer 110 includes a first surface 111 and a second surface 112. The second surface 112 is opposed to the first surface 111.

In the present preferred embodiment, the thickness of the piezoelectric layer 110 is from about 0.3 μm to about 5.0 μm and is preferably from about 0.5 μm to about 1.0 μm, for example.

The piezoelectric layer 110 is monocrystalline. The cut direction of the piezoelectric layer 110 is appropriately selected such that the piezoelectric element 100 exhibits desired device characteristics. In the present preferred embodiment, the piezoelectric layer 110 includes a monocrystalline substrate and is specifically a rotated Y-cut substrate, for example. The cut direction of the rotated Y-cut substrate is, for example, about 30°. When the cut direction of the rotated Y-cut substrate is about 30°, the displacement of bending vibration of a membrane section described below is larger.

The material of the piezoelectric layer 110 is appropriately selected such that the piezoelectric element 100 exhibits desired device characteristics. In the present preferred embodiment, the piezoelectric layer 110 is made of, for example, an alkali niobate-based compound or an alkali tantalate-based compound. The piezoelectric constant of these compounds is relatively high and is higher than the piezoelectric constant of, for example, aluminum nitride (AlN). In the present preferred embodiment, an alkali metal included in the alkali niobate-based compound or the alkali tantalate-based compound is, for example, at least one of lithium, sodium, and potassium. In the present preferred embodiment, the piezoelectric layer 110 is made of, for example, lithium niobate (LiNbO₃) or lithium tantalate (LiTaO₃).

As illustrated in FIG. 2, the first electrode layer 120 is disposed on the first surface 111. A contact layer may be disposed between the first electrode layer 120 and the piezoelectric layer 110.

As illustrated in FIGS. 1 and 3, the first electrode layer 120 includes a counter electrode section 121, a wiring section 122, and an outer electrode section 123. In the present preferred embodiment, the counter electrode section 121 is located at the center or substantially the center of the piezoelectric element 100 and has a circular or substantially circular shape as viewed in a direction perpendicular or substantially perpendicular to the first surface 111. As illustrated in FIG. 3, the outer electrode section 123 is located on an end portion of the first surface 111 in an in-plane direction thereof. The wiring section 122 connects the counter electrode section 121 and the outer electrode section 123 together.

In the present preferred embodiment, the thickness of the first electrode layer 120 is, for example, from about 0.05 μm to about 0.2 μm. The thickness of contact layer is, for example, from about 0.005 μm to about 0.05 μm.

In the present preferred embodiment, the first electrode layer 120 is made of, for example, Pt. The first electrode layer 120 may be made of another material such as, for example, Al. The first electrode layer 120 and the contact layer may be, for example, epitaxially grown films.

In the present preferred embodiment, the contact layer is made of, for example, Ti. The contact layer may be made of another material such as, for example, NiCr. When the piezoelectric layer 110 is made of lithium niobate (LiNbO₃), the contact layer is preferably made of, for example, NiCr rather than Ti from the viewpoint of reducing or preventing the diffusion of material of the contact layer into the first electrode layer 120. This improves the reliability of the piezoelectric element 100.

As illustrated in FIG. 2, the second electrode layer 130 is disposed on the second surface 112. At least a portion of the second electrode layer 130 faces the first electrode layer 120 with the piezoelectric layer 110 interposed therebetween. In the present preferred embodiment, the second electrode layer 130 faces the counter electrode section 121 with the piezoelectric layer 110 interposed therebetween.

In the present preferred embodiment, the thickness of the second electrode layer 130 is greater than the thickness of the piezoelectric layer 110. The thickness of the second electrode layer 130 is, for example, from about 0.5 μm to about 50 μm.

The second electrode layer 130 mainly includes silicon, for example. In the present preferred embodiment, the second electrode layer 130 mainly includes monocrystalline silicon, for example. Specifically, the second electrode layer 130 is made of monocrystalline silicon doped with an element that reduces the electrical resistivity of the second electrode layer 130. In the present preferred embodiment, the second electrode layer 130 is doped with an element such as, for example, B, P, Sb, or Ge or a combination of these elements (for example, a combination of B and Ge). In the present preferred embodiment, the electrical resistivity of the second electrode layer 130 is, for example, from about 0.1 mΩ·cm to about 100 mΩ·cm.

In the present preferred embodiment, an interface 190 between the second electrode layer 130 and the piezoelectric layer 110 includes an interface junction formed by surface activated bonding or atomic diffusion bonding, for example.

In the present preferred embodiment, as illustrated in FIG. 2, a multilayer body 101 includes at least the first electrode layer 120, the piezoelectric layer 110, and the second electrode layer 130. As illustrated in FIG. 3, the multilayer body 101 further includes the first connection electrode 150 and the second connection electrode 160. The base section 140 supports the multilayer body 101.

As illustrated in FIG. 2, the base section 140 is located on the second electrode layer 130 side of the multilayer body 101. As illustrated in FIG. 1, the base section 140 is circularly shaped so as to follow the periphery of the multilayer body 101 as viewed in a deposition direction of the multilayer body 101.

In the present preferred embodiment, as illustrated in FIG. 2, the base section 140 includes a silicon oxide layer 141 and a base body 142. The silicon oxide layer 141 is in contact with the second electrode layer 130. The base body 142 is in contact with the silicon oxide layer 141 on the opposite side of the silicon oxide layer 141 from the second electrode layer 130 side. In the present preferred embodiment, a material of the base body 142 is not particularly limited and the base body 142 includes, for example, monocrystalline silicon.

As illustrated in FIGS. 1 and 2, an opening 143 is located inside the base section 140 as viewed in the deposition direction. The opening 143 has a circular or substantially circular shape as viewed in the deposition direction.

As illustrated in FIGS. 1 and 3, the first connection electrode 150 is located on the upper side of the outer electrode section 123 of the first electrode layer 120. A contact layer may be located between the first connection electrode 150 and the first electrode layer 120.

The thickness of the first connection electrode 150 is, for example, from about 0.1 μm to about 1.0 μm. The thickness of a contact layer connected to the first connection electrode 150 is, for example, from about 0.005 μm to about 0.1 μm.

As illustrated in FIG. 3, the second connection electrode 160 is disposed on a portion of a surface of the second electrode layer 130, the surface being located on the piezoelectric layer 110 side, the portion not being covered by the piezoelectric layer 110. This enables continuity from a member external to the piezoelectric element 100 to the second electrode layer 130 to be ensured with the second connection electrode 160 interposed therebetween. The second connection electrode 160 and the second electrode layer 130 are in ohmic contact with each other.

In the present preferred embodiment, the first connection electrode 150 and the second connection electrode 160 are made of, for example, Au. The first connection electrode 150 and the second connection electrode 160 may be made of another conductive material such as, for example, Al. The contact layer located between the first connection electrode 150 and the first electrode layer 120 is made of, for example, Ti. The contact layer may be made of, for example, NiCr.

In the present preferred embodiment, as illustrated in FIGS. 1 and 2, the multilayer body 101 includes a membrane section 102. The membrane section 102 overlaps the opening 143 and does not overlap the base section 140 as viewed in the deposition direction. As illustrated in FIG. 2, the width size of the membrane section 102 in a direction parallel or substantially parallel to the second surface 112 is set to be at least about five times or more the thickness size of the membrane section 102 in a direction perpendicular or substantially perpendicular to the second surface 112.

In the present preferred embodiment, as illustrated in FIGS. 1 and 2, the multilayer body 101 includes a plurality of slits 103 extending through the multilayer body 101 from the first electrode layer 120 side to the second electrode layer 130 side. Each of the slits 103 communicates with the opening 143. The slits 103 extend so as to radiate from the center or substantially the center of the piezoelectric element 100 as viewed in a direction perpendicular or substantially perpendicular to the first surface 111.

Since the slits 103 are provided, the membrane section 102 of the multilayer body 101 includes a plurality of beam sections 105. In the present preferred embodiment, as illustrated in FIG. 1, each of the beam sections 105 connects a section of the multilayer body 101 that excludes the membrane section 102 to a plate-shaped portion 104 that is a portion where the counter electrode section 121 of the multilayer body 101 is located as viewed in a direction perpendicular or substantially perpendicular to the first surface 111. Each of the beam sections 105 is convexly curved in a direction following an outer edge of the membrane section 102 as viewed in a direction perpendicular or substantially perpendicular to the first surface 111. The profile of each of the beam sections 105 is not particularly limited. In the present preferred embodiment, since the slits 103 are provided, the beam sections 105 are located side by side in a direction following the outer edge of the membrane section 102.

In the present preferred embodiment, the membrane section 102 has a unimorph structure as described above. The membrane section 102 undergoes bending vibration, thus enabling the piezoelectric element 100 according to the present preferred embodiment to transmit and receive an ultrasonic wave. In order to allow the membrane section 102 to undergo bending vibration, a voltage is applied to the piezoelectric layer 110.

In the piezoelectric element 100 according to the present preferred embodiment, a voltage V is applied between the first connection electrode 150 and second connection electrode 160 illustrated in FIG. 3, such that a voltage is applied between the first electrode layer 120 and second electrode layer 130 illustrated in FIG. 2. This drives the piezoelectric layer 110, which is located between the first electrode layer 120 and the second electrode layer 130. At this time, the voltage V applied between the first connection electrode 150 and the second connection electrode 160 is divided and therefore a portion of the voltage V is applied to the piezoelectric layer 110. The division of the voltage V is described below.

FIG. 4 is a diagram illustrating an equivalent circuit of the piezoelectric element according to the first preferred embodiment of the present invention. As illustrated in FIG. 4, the piezoelectric element 100 includes a circuit in which the piezoelectric layer 110, which has an electrostatic capacitance C, and the second electrode layer 130, which has a resistance R, are connected to each other in series. This allows the voltage V applied between the first connection electrode 150 and the second connection electrode 160 to be divided between the piezoelectric layer 110 and the second electrode layer 130.

Herein, the piezoelectric layer 110, which has an electrostatic capacitance C, has an electrical impedance provided by the formula (1/jωC). In the formula, j is a complex number and ω is the driving angular frequency. As illustrated by the formula, as the electrostatic capacitance is larger, the electrical impedance tends to be lower.

For example, in the piezoelectric element 100 illustrated in FIG. 2, when the thickness of the piezoelectric layer 110 is about 1 μm, the width of the plate-shaped portion 104 in the in-plane direction of the second surface 112 is about 0.8 mm, and the relative permittivity of the piezoelectric layer 110 which is monocrystalline is about 50, the electrical impedance calculated from the electrostatic capacitance C of the piezoelectric layer 110 is about 14 kΩ. Assuming that the resistivity of the second electrode layer 130 is about 1 mΩ·cm, the length of a path from the plate-shaped portion 104 to the second connection electrode 160 as viewed in a direction perpendicular or substantially perpendicular to the second surface 112 as illustrated in FIG. 1 is about 0.1 mm, the width of the second electrode layer 130 in the path is about 0.8 mm, and the thickness of the second electrode layer 130 in a direction perpendicular to the second surface 112 is about 1 μm, the resistance R of the second electrode layer 130 is about 4 kΩ. In the piezoelectric element 100 under such conditions, about 78% (=14/(14+4)) of the applied voltage V is applied to the piezoelectric layer 110.

On the other hand, in the piezoelectric element 100, which has the above structure, a case where the material of the piezoelectric layer 110 is changed to a polycrystalline piezoelectric with a permittivity relatively higher than that of a monocrystalline piezoelectric has been researched. When the piezoelectric layer 110 is polycrystalline and has a relative permittivity of about 500, the electrical impedance of the piezoelectric layer 110 is about 1.6 kΩ. Then, in the piezoelectric element 100 under such conditions, about 29% (=1.6/(1.6+4)) of the applied voltage V is applied to the piezoelectric layer 110. When the piezoelectric layer 110 is polycrystalline as described above, the applied voltage is low as compared to when the piezoelectric layer 110 is monocrystalline.

As described above, in the present preferred embodiment, forming the piezoelectric layer 110 using a monocrystalline material enables the driving efficiency of the piezoelectric element 100 to be improved.

Next, details of a function of the piezoelectric element 100 according to the first preferred embodiment of the present invention are described.

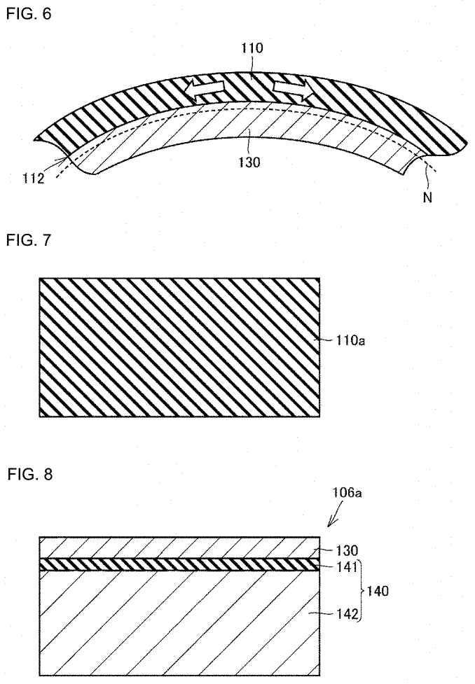

FIG. 5 is a schematic view of a portion of the membrane section of the piezoelectric element according to the first preferred embodiment of the present invention. FIG. 6 is a schematic view of a portion of the membrane section, in operation, of the piezoelectric element according to the first preferred embodiment of the present invention.

As illustrated in FIG. 5, the piezoelectric layer 110 is located on one side of a stress neutral plane N of the membrane section 102 only. This allows the membrane section 102 to undergo large bending vibration as illustrated in FIG. 6 when the piezoelectric layer 110 is driven.

Specifically, in the membrane section 102, the piezoelectric layer 110 is an elastic layer and layers, such as the second electrode layer 130, other than the piezoelectric layer 110 are constraining layers. As illustrated in FIG. 6, in the membrane section 102, when the piezoelectric layer 110, which is the elastic layer, expands or contracts in an in-plane direction, the expansion or contraction thereof is restricted by the second electrode layer 130, which is a main layer among the constraining layers. Therefore, the membrane section 102 is bent in a direction perpendicular to the second surface 112. As the distance between the stress neutral plane N and the second surface 112 of the piezoelectric layer 110 is longer, the membrane section 102 vibrates more significantly.

The piezoelectric element 100 according to the first preferred embodiment of the present invention can be used, for example, as a microelectromechanical system (MEMS) device because the membrane section 102 vibrates significantly as described above. The MEMS device is, for example, an audio microphone, an audio speaker, an ultrasonic transducer, or the like.

In the present preferred embodiment, for example, as illustrated in FIG. 1, the piezoelectric element 100 has a rectangular or substantially rectangular shape and a side with a length of about 1 mm to about 2 mm when the piezoelectric element 100 is viewed from the first electrode layer 120 side. This enables the piezoelectric element 100 to be used as the MEMS device.

Furthermore, in a case where the piezoelectric element 100 is used as an ultrasonic transducer, the shape, thickness, and the like of the membrane section 102 are designed such that the mechanical resonance of the membrane section 102 occurs at a frequency of, for example, about 20 kHz or more, which is a non-audible frequency. In the present preferred embodiment, for example, when the length of a side of the piezoelectric element 100 is about 1.2 mm as viewed in a direction perpendicular or substantially perpendicular to the first surface 111, the diameter of the membrane section 102 is set to, for example, about 0.8 mm such that the transmission-reception area for ultrasonic waves is maximized. In the piezoelectric element 100 designed as described above, in a case where an ultrasonic wave with a frequency of 40 kHz is transmitted or received, the thickness of the membrane section 102 is set to, for example, a range of about 2 μm to about 5 μm.

In the piezoelectric element 100 according to the present preferred embodiment, a portion of a substrate used in a non-limiting example of a method for manufacturing the piezoelectric element 100 described below acts as the second electrode layer 130 as-is. This allows the thickness of the membrane section 102 to be relatively small as in the above numerical range.

A non-limiting example of a method for manufacturing the piezoelectric element according to the first preferred embodiment of the present invention is described below. In FIGS. 7 to 14, the same cross section as that in FIG. 2 is illustrated.

FIG. 7 is an illustration in which a piezoelectric monocrystalline substrate is prepared in the method for manufacturing the piezoelectric element according to the first preferred embodiment of the present invention. As illustrated in FIG. 7, a piezoelectric monocrystalline substrate 110a is prepared. The piezoelectric monocrystalline substrate 110a is processed into the piezoelectric layer 110 later.

FIG. 8 is an illustration in which a multilayer substrate including a second electrode layer is prepared in the method for manufacturing the piezoelectric element according to the first preferred embodiment of the present invention. As illustrated in FIG. 8, a multilayer substrate 106a including the second electrode layer 130 and the base section 140 is prepared. In the present preferred embodiment, the multilayer substrate 106a is, for example, a silicon-on-insulator (SOI) substrate.

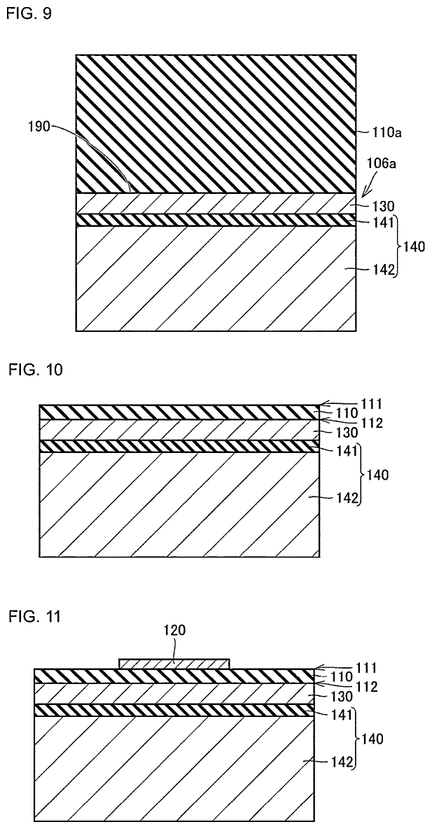

FIG. 9 is an illustration illustrating a state in which the piezoelectric monocrystalline substrate is bonded to the multilayer substrate including the second electrode layer in the method for manufacturing the piezoelectric element according to the first preferred embodiment of the present invention. As illustrated in FIG. 9, the piezoelectric monocrystalline substrate 110a is bonded to the second electrode layer 130 side of the multilayer substrate 106a by, for example, surface activated bonding or atomic diffusion bonding. This allows the interface 190, which includes the interface junction, to be formed between the multilayer substrate 106a and the piezoelectric monocrystalline substrate 110a. Before bonding, a faying surface of each of the multilayer substrate 106a and the piezoelectric monocrystalline substrate 110a is preferably planarized in advance by, for example, chemical mechanical polishing (CMP). Planarizing the faying surface in advance increases the manufacturing yield of the piezoelectric element 100.

FIG. 10 is a sectional view illustrating a state in which the piezoelectric layer is formed by grinding the piezoelectric monocrystalline substrate in the method for manufacturing the piezoelectric element according to the first preferred embodiment of the present invention. As illustrated in FIGS. 9 and 10, the piezoelectric layer 110 is formed such that a portion of the piezoelectric monocrystalline substrate 110a that is on the opposite side from the second electrode layer 130 side is thinned by grinding using, for example, a grinder and is then planarized by polishing such as, for example, CMP.

A release layer may be formed on the opposite side of the piezoelectric monocrystalline substrate 110a from the faying surface side by, for example, ion implantation in advance. Before the piezoelectric monocrystalline substrate 110a is bonded to the multilayer substrate 106a, the release layer is formed, thus enabling the piezoelectric layer 110 to be formed by peeling off the release layer after bonding. The piezoelectric layer 110 may be formed such that after the release layer is peeled off, the piezoelectric monocrystalline substrate 110a is further polished by, for example, CMP or the like.

In the present preferred embodiment, as illustrated in FIGS. 7 to 10, the second electrode layer 130 is bonded to the second surface 112 side of the piezoelectric layer 110, which includes the first surface 111 and the second surface 112 opposed to the first surface 111, by, for example, surface activated bonding or atomic diffusion bonding. As described above, the method for manufacturing the piezoelectric element 100 according to the present preferred embodiment includes a step of bonding the second electrode layer 130 to the piezoelectric layer 110.

FIG. 11 is a sectional view illustrating a state in which a first electrode layer is disposed in the method for manufacturing the piezoelectric element according to the first preferred embodiment of the present invention. As illustrated in FIG. 11, the first electrode layer 120 is deposited on the first surface 111 side of the piezoelectric layer 110 such that at least a portion of the first electrode layer 120 faces the second electrode layer 130 with the piezoelectric layer 110 interposed therebetween. As described above, the method for manufacturing the piezoelectric element 100 according to the first preferred embodiment of the present invention includes a step of depositing the first electrode layer 120. Before the first electrode layer 120 is disposed, the contact layer located between the first electrode layer 120 and the piezoelectric layer 110 may be deposited.

In the present preferred embodiment, the first electrode layer 120 is formed by, for example, a vapor deposition lift-off process so as to have a desired pattern. The first electrode layer 120 may be formed such that after the first electrode layer 120 is deposited over the first surface 111 of the piezoelectric layer 110 by, for example, sputtering, a desired pattern is formed by, for example, an etching process.

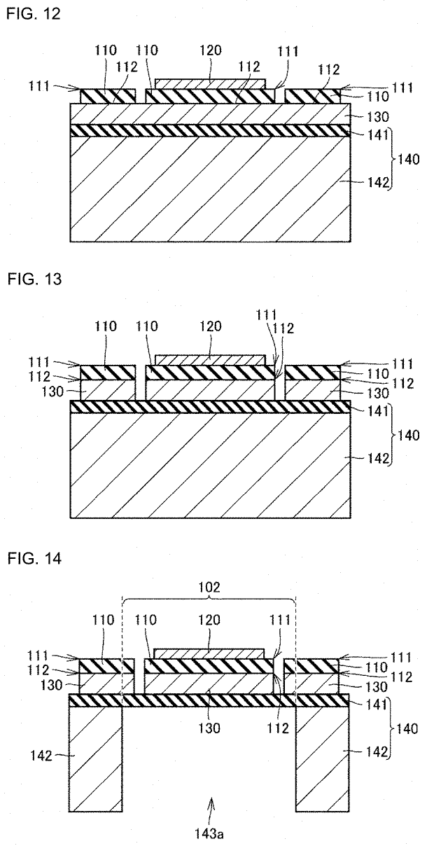

FIG. 12 is a sectional view illustrating a state in which pores and the like are formed in the piezoelectric layer in the method for manufacturing the piezoelectric element according to the first preferred embodiment of the present invention. As illustrated in FIG. 12, a plurality of pores are formed by, for example, reactive ion etching (RIE) so as to correspond to the slits 103, which are located in the membrane section 102 as illustrated in FIG. 2. As illustrated in FIG. 3, a notch for placing the second connection electrode 160 on the second electrode layer 130 is formed together with the pores. The pores and the notch may be formed by, for example, wet etching using fluoronitric acid or the like.

FIG. 13 is a sectional view illustrating a state in which pores and the like are formed in the second electrode layer in the method for manufacturing the piezoelectric element according to the first preferred embodiment of the present invention. As illustrated in FIG. 13, the pores and the like are formed by, for example, deep reactive ion etching (deep RIE). The pores correspond to the slits 103 of the piezoelectric element 100 according to the present preferred embodiment.

Next, as illustrated in FIG. 3, the first connection electrode 150 is formed by, for example, the vapor deposition lift-off process so as to have a desired pattern. After the first connection electrode 150 is deposited over the first surface 111 side of the piezoelectric layer 110, the desired pattern may be formed by, for example, an etching process.

Next, the second connection electrode 160 is deposited on the piezoelectric layer 110 exposed by forming the notch. The deposition allows the piezoelectric layer 110 and the second connection electrode 160 to be in ohmic contact with each other. When the piezoelectric layer 110 and the second connection electrode 160 are not in ohmic contact with each other, annealing is performed immediately after the second connection electrode 160 is deposited on the piezoelectric layer 110. The temperature and time of annealing are appropriately set in consideration of the conductivity of the second electrode layer 130.

FIG. 14 is an illustration illustrating a state in which an opening is provided on the opposite side of the multilayer substrate, which includes the second electrode layer, from the second electrode layer side in the method for manufacturing the piezoelectric element according to the first preferred embodiment of the present invention. As illustrated in FIG. 14, a concave section 143a corresponding to the opening 143 of the present preferred embodiment is formed from the opposite side of the base section 140 from the second electrode layer 130 side by, for example, deep reactive ion etching (deep RIE).

Finally, the silicon oxide layer 141 forming the bottom of the concave section 143a is polished by, for example, RIE, such that the opening 143 is formed as illustrated in FIG. 2.

Through the above steps, the piezoelectric element 100 according to the first preferred embodiment of the present invention is manufactured as illustrated in FIGS. 1 to 3.

As described above, in the piezoelectric element 100 according to a preferred embodiment of the present invention, at least the portion of the second electrode layer 130 faces the first electrode layer 120 with the piezoelectric layer 110 interposed therebetween. The second electrode layer 130 mainly includes silicon, for example. The piezoelectric layer 110 is monocrystalline, for example.

This allows no grain boundaries to be present in the piezoelectric layer 110, which is monocrystalline. Therefore, the permittivity of the piezoelectric layer 110 is low and, in association with this, the electrostatic capacitance of the piezoelectric layer 110 is low. Thus, the voltage distributed to the piezoelectric layer 110 is high and therefore the driving efficiency of the piezoelectric element 100 increases.

In the present preferred embodiment, the second electrode layer 130 mainly includes, for example, monocrystalline silicon. This allows the second electrode layer 130 to be used as a substrate or a portion of a substrate as-is. Therefore, the stress load of the piezoelectric layer 110 can be reduced. Furthermore, the occurrence of cracks in the piezoelectric layer 110 can be reduced and the yield of the piezoelectric element 100 can be increased.

In the present preferred embodiment, the piezoelectric layer 110 is made of, for example, the alkali niobate-based compound or the alkali tantalate-based compound.

This enables the driving efficiency of the piezoelectric element 100 to be increased because the piezoelectric layer 110 is made of material with a relatively high piezoelectric constant.

In the present preferred embodiment, the piezoelectric layer 110 is made of, for example, lithium niobate.

This allows the piezoelectric constant of the piezoelectric layer 110 to be high as compared to when the piezoelectric layer 110 is made of another alkali niobate-based compound or another alkali tantalate-based compound. Therefore, device characteristics of the piezoelectric element 100 can be improved.

In the present preferred embodiment, the piezoelectric layer 110 is made of, for example, lithium tantalate.

This allows the permittivity of the piezoelectric layer 110 to be low as compared to when the piezoelectric layer 110 is made of another alkali niobate-based compound or another alkali tantalate-based compound. Therefore, the driving efficiency of the piezoelectric element 100 increases and device characteristics of the piezoelectric element 100 can be improved.

The piezoelectric element 100 according to the present preferred embodiment further includes the base section 140, which supports the multilayer body 101 including at least the first electrode layer 120, the piezoelectric layer 110, and the second electrode layer 130. The base section 140 is located on the second electrode layer 130 side of the multilayer body 101 and is shaped so as to follow the periphery of the multilayer body 101 as viewed in the deposition direction of the multilayer body 101.

This enables the driving of the piezoelectric layer 110 to be converted into the bending vibration of the membrane section 102.

In the present preferred embodiment, the base section 140 includes the silicon oxide layer 141, which is in contact with the second electrode layer 130. The second electrode layer 130 is made of monocrystalline silicon doped with the element that reduces the electrical resistivity of the second electrode layer 130.

This enables the second electrode layer 130 to be used as a substrate or a portion of a substrate. Therefore, an electrode layer that faces the first electrode layer 120 with the piezoelectric layer 110 interposed therebetween need not be separately disposed. This allows the thickness of the whole membrane section 102 to be small. Furthermore, the second electrode layer 130 defines and functions as a substrate. Therefore, the number of layers that are deposited can be reduced and the stress acting on the membrane section 102 can be reduced. Thus, the manufacturing yield of the piezoelectric element 100 can be increased.

In the present preferred embodiment, the multilayer body 101 is provided with the slits 103, which extends through the multilayer body 101 from the first electrode layer 120 side to the second electrode layer 130 side. The slits 103 communicate with the opening 143, which is located inside the base section 140 as viewed in a deposition direction.

This allows the membrane section 102 to be provided with the beam sections 105. The beam sections 105 increase the efficiency of bending vibration of the membrane section 102.

In the present preferred embodiment, the thickness of the second electrode layer 130 is greater than the thickness of the piezoelectric layer 110.

This allows the thickness of the piezoelectric layer 110 to be relatively small. Therefore, the processing of the piezoelectric layer 110 by, for example, etching or the like is facilitated. Since the thickness of the second electrode layer 130 is relatively large, the occurrence of unnecessary etching on the opposite side of the second electrode layer 130 from the piezoelectric layer 110 side can be reduced or prevented even if the second electrode layer 130 is unnecessarily etched when the piezoelectric layer 110 is etched. Furthermore, the stress neutral plane of the membrane section 102 is located in the second electrode layer 130 and therefore the efficiency of bending vibration of the membrane section 102 increases.

In the present preferred embodiment, the interface 190 between the second electrode layer 130 and the piezoelectric layer 110 includes the interface junction formed by, for example, surface activated bonding or atomic diffusion bonding. This enables the second electrode layer 130 and the piezoelectric layer 110 to be reduced or prevented from chemically reacting with each other, thus enabling the reduction in device characteristics of the piezoelectric element 100 to be reduced or prevented.

The method for manufacturing the piezoelectric element 100 according to the first preferred embodiment of the present invention includes the step of bonding the second electrode layer 130 and the step of depositing the first electrode layer 120. In the step of bonding the second electrode layer 130, the second electrode layer 130 is bonded, by, for example, surface activated bonding or atomic diffusion bonding, to the second surface 112 side of the piezoelectric layer 110, which includes the first surface 111 and the second surface 112 opposed to the first surface 111. In the step of depositing the first electrode layer 120, the first electrode layer 120 is deposited on the first surface 111 side of the piezoelectric layer 110 such that at least a portion of the first electrode layer 120 faces the second electrode layer 130 with the piezoelectric layer 110 interposed therebetween. The second electrode layer 130 mainly includes, for example, silicon. The piezoelectric layer 110 is, for example, monocrystalline.

This allows no grain boundaries to be present in the piezoelectric layer 110, which is monocrystalline. Therefore, the permittivity of the piezoelectric layer 110 is low and, in association with this, the electrostatic capacitance of the piezoelectric layer 110 is low. Thus, the voltage distributed to the piezoelectric layer 110 is high and therefore the driving efficiency of the piezoelectric element 100 increases. The second electrode layer 130 and the piezoelectric layer 110 can be reduced or prevented from chemically reacting with each other.

### Second Preferred Embodiment

A piezoelectric element according to a second preferred embodiment of the present invention is described below. The piezoelectric element according to the second preferred embodiment of the present invention differs mainly from the piezoelectric element 100 according to the first preferred embodiment of the present invention in that a plurality of beam sections are driven. Thus, the same or substantially the same components as those of the piezoelectric element 100 according to the first preferred embodiment of the present invention will not be repeatedly described.

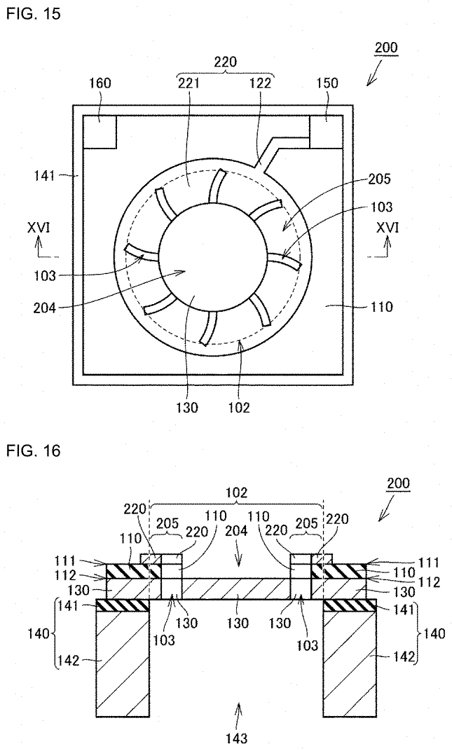

FIG. 15 is a plan view of the piezoelectric element according to the second preferred embodiment of the present invention. FIG. 16 is a sectional view of the piezoelectric element viewed in the direction of an arrow of the line XVI-XVI of FIG. 15.

In the piezoelectric element 200 according to the second preferred embodiment of the present invention, as illustrated in FIGS. 15 and 16, a counter electrode section 221 of a first electrode layer 220 is disposed on a piezoelectric layer 110 in each of the beam sections 205. The first electrode layer 220 is not located on a plate-shaped portion 204 of a membrane section 102 that is located inside the beam sections 205 as viewed in a deposition direction. This allows the plate-shaped portion 204 to be significantly displaced in the deposition direction by the bending vibration of the beam sections 205, thus enabling an ultrasonic wave to be transmitted or received.

Also in the present preferred embodiment, at least a portion of a second electrode layer 130 faces the first electrode layer 220 with the piezoelectric layer 110 interposed therebetween. The second electrode layer 130 mainly includes, for example, silicon. The piezoelectric layer 110 is, for example, monocrystalline. This increases the driving efficiency of the piezoelectric element 200.

### Third Preferred Embodiment

A piezoelectric element according to a third preferred embodiment of the present invention is described below. The piezoelectric element according to the third preferred embodiment of the present invention differs mainly from the piezoelectric element 100 according to the first preferred embodiment of the present invention in the shape of a plurality of beam sections. Thus, the same or substantially the same components as those of the piezoelectric element 100 according to the first preferred embodiment of the present invention will not be repeatedly described.

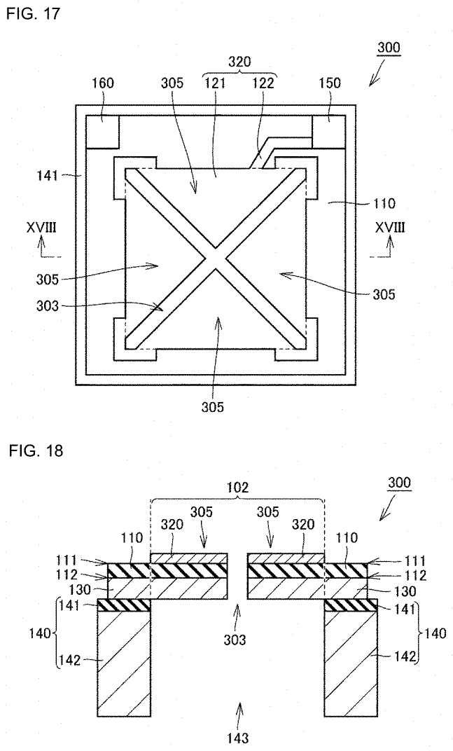

FIG. 17 is a plan view of the piezoelectric element according to the third preferred embodiment of the present invention. FIG. 18 is a sectional view of the piezoelectric element viewed in the direction of an arrow of the line XVIII-XVIII of FIG. 17.

In the piezoelectric element 300 according to the third preferred embodiment of the present invention, a plurality of slits 303 in a membrane section 102 communicate with each other at the center or approximate center of the membrane section 102 as viewed in the deposition direction. This allows each of a plurality of beam sections 305 to have a cantilevered shape. In the membrane section 102, a first electrode layer 320 is located over a first surface 111 of a piezoelectric layer 110.

In the present preferred embodiment, the beam sections 305 undergo bending vibration to significantly displace a tip portion of each of the beam sections 305 in the deposition direction, thus enabling an ultrasonic wave to be transmitted or received.

Also in the present preferred embodiment, at least a portion of a second electrode layer 130 faces the first electrode layer 320 with the piezoelectric layer 110 interposed therebetween. The second electrode layer 130 mainly includes, for example, silicon. The piezoelectric layer 110 is, for example, monocrystalline. This increases the driving efficiency of the piezoelectric element 300.

In the description of above-described preferred embodiments, combinable components may be combined with each other.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric element comprising:
a piezoelectric layer including a first surface and a second surface opposed to the first surface;
a first electrode layer on the first surface; and
a second electrode layer on the second surface, at least a portion of the second electrode layer facing the first electrode layer with the piezoelectric layer interposed therebetween; wherein
the second electrode layer mainly includes silicon; and
the piezoelectric layer is monocrystalline.

2. The piezoelectric element according to claim 1, wherein the second electrode layer mainly includes monocrystalline silicon.

3. The piezoelectric element according to claim 1, wherein the piezoelectric layer includes an alkali niobate-based compound or an alkali tantalate-based compound.

4. The piezoelectric element according to claim 3, wherein the piezoelectric layer includes lithium niobate.

5. The piezoelectric element according to claim 3, wherein the piezoelectric layer includes lithium tantalate.

6. The piezoelectric element according to claim 1, further comprising:
a base section supporting a multilayer body including at least the first electrode layer, the piezoelectric layer, and the second electrode layer; wherein
the base section is located on a side of the second electrode layer of the multilayer body and follows a periphery of the multilayer body as viewed in a deposition direction of the multilayer body.

7. The piezoelectric element according to claim 6, wherein
the base section includes a silicon oxide layer in contact with the second electrode layer; and
the second electrode layer includes monocrystalline silicon doped with an element that reduces an electrical resistivity of the second electrode layer.

8. The piezoelectric element according to claim 6, wherein
the multilayer body includes a slit extending through the multilayer body from a side of the first electrode layer to the side of the second electrode layer; and
the slit communicates with an opening located inside the base section as viewed in the deposition direction.

9. The piezoelectric element according to claim 7, wherein a thickness of the second electrode layer is greater than a thickness of the piezoelectric layer.

10. The piezoelectric element according to claim 1, wherein an interface between the second electrode layer and the piezoelectric layer includes an interface junction that is surface activated bonded or atomic diffusion bonded.

11. A method for manufacturing a piezoelectric element, the method comprising:
bonding, by surface activated bonding or atomic diffusion bonding, a second electrode layer to a side of a second surface of a piezoelectric layer including a first surface and the second surface located opposed to the first surface; and
depositing a first electrode layer on a side of the first surface of the piezoelectric layer such that at least a portion of the first electrode layer faces the second electrode layer with the piezoelectric layer interposed therebetween; wherein
the second electrode layer mainly includes silicon; and
the piezoelectric layer is monocrystalline.

12. The method for manufacturing a piezoelectric element according to claim 11, wherein the second electrode layer mainly includes monocrystalline silicon.

13. The method for manufacturing a piezoelectric element according to claim 11, wherein the piezoelectric layer includes an alkali niobate-based compound or an alkali tantalate-based compound.

14. The method for manufacturing a piezoelectric element according to claim 13, wherein the piezoelectric layer includes lithium niobate.

15. The method for manufacturing a piezoelectric element according to claim 13, wherein the piezoelectric layer includes lithium tantalate.

16. The method for manufacturing a piezoelectric element according to claim 11, wherein
the piezoelectric element includes:
a base section supporting a multilayer body including at least the first electrode layer, the piezoelectric layer, and the second electrode layer; wherein
the base section is located on a side of the second electrode layer of the multilayer body and follows a periphery of the multilayer body as viewed in a deposition direction of the multilayer body.

17. The method for manufacturing a piezoelectric element according to claim 16, wherein
the base section includes a silicon oxide layer in contact with the second electrode layer; and
the second electrode layer includes monocrystalline silicon doped with an element that reduces an electrical resistivity of the second electrode layer.

18. The method for manufacturing a piezoelectric element according to claim 16, wherein
the multilayer body includes a slit extending through the multilayer body from a side of the first electrode layer to the side of the second electrode layer; and
the slit communicates with an opening located inside the base section as viewed in the deposition direction.

19. The method for manufacturing a piezoelectric element according to claim 17, wherein a thickness of the second electrode layer is greater than a thickness of the piezoelectric layer.

20. The method for manufacturing a piezoelectric element according to claim 11, wherein an interface between the second electrode layer and the piezoelectric layer includes an interface junction that is surface activated bonded or atomic diffusion bonded.
